(19) United States
(12) Patent Application Publication
(10) Pub. No.: US 2012/0175255 A1
(43) Pub. Date: Jul. 12, 2012

(54) AFFINITY CAPILLARY ELECTROPHORESIS METHOD FOR ASSESSING A BIOLOGICAL INTERACTION OF A LIGAND/RECEPTOR PAIR SUCH AS G PROTEIN COUPLED RECEPTOR AND ITS TARGETS AS WELL AS FOR DRUG SCREENING

(76) Inventor: Dallas Hughes, Ongar (GB)

(21) Appl. No.: 13/497,598

(22) PCT Filed: Sep. 20, 2010
(86) PCT No.: PCT/GB10/51574

§ 371 Date: Mar. 22, 2012

(30) Foreign Application Priority Data
Sep. 22, 2009 (GB) 0916636.4
Apr. 19, 2010 (GB) 1006496.2

(51) Int. Cl. G01N 27/447; B81B 1/00

(52) U.S. Cl. 204/453

(57) ABSTRACT

The invention relates to capillary electrophoresis-based methods for screening compound libraries for affinity lig- ands, in particular weak-binding ligands.

The present invention relates to a capillary electrophoresis method for screening compound libraries for ligands against particular targets, in particular screening for weak-binding ligands.

There are many assays available for the screening of novel compounds and existing compound libraries, each being devised to provide particular advantages and information. Binding assays are a good starting point to ascertain whether a chemical backbone or specific chemical entities will bind to a target of interest. In such assays, the target of interest may be immobilised on a solid substrate such as a bead, chromatographic support or the wall of a microtiter well. Alternatively, the target may be expressed on the membrane of a cell, which is then immobilised. The immobilised target is then incubated with a test compound and binding is detected using calorimetry or fluorescence. Binding interactions using calorimetry or fluorescence may also be determined using proteins in solution phase (e.g. fluorescence polarization).

An alternative screening method that provides all the needs of high throughput capacity, robustness and simplicity is capillary electrophoresis. Capillary electrophoresis relies on the movement of ions through a thin capillary tube under the influence of an applied electric field. Ions of opposite charge to electrodes on either end of the voltage will migrate toward that electrode. Thus, ions that are negatively charged will move or migrate toward the positively charged electrode and vice versa for the positively charged ions. This is known as “electrophoretic mobility”. Capillary electrophoresis is a powerful tool because each ion will migrate at a different rate with high resolution, due to the ion's quantity of charge compared to its relative hydrodynamic size, its charge-to-mass ratio. The actual mobility of an ion takes into account the environment in which the ion exists in during capillary electrophoresis. For example, electrophoretic mobility will differ from actual mobility when viscosity changes and different voltages are applied. Ions also can move under the influence of electro-osmotic flow, which occurs when a negative charge on the inner glass surface of the capillary produces a bulk flow of liquid towards the cathode, enabling the migration and detection of uncharged ligands.

A typical capillary electrophoresis apparatus includes a cathode, an anode, a high voltage power supply, and an aqueous buffer solution that fills the capillary and is present in buffer chambers at each end of the capillary. The anode and cathode are immersed in the two buffer chambers along with the capillary ends. The apparatus also includes a detector and a data output and handling device.

Samples are introduced into the capillary by two different methods. Electrokinetic injection can be used to introduce analytes carrying an electric charge and is accomplished by placing one end of the capillary into the sample to be injected and briefly applying an electric field. Under these conditions, the sample analyte(s) migrate into the capillary based on their electrophoretic mobility. Hydrodynamic injection is a more general method and requires the application of pressure or a vacuum to one end of the capillary. The pressure differential between the two opposite ends of the capillary introduces the analyte into the capillary for subsequent electrophoretic analysis.

Once injected, the migration of the analytes is then initiated by an electric field that is applied between the buffer chambers at each end of the capillary and is supplied to the electrodes by the high-voltage power supply. The direction of electrophoresis can be either from the anode (injection end) to the cathode (outlet end), or vice versa, depending on the charge of the analyte. If sufficient electroosmotic flow is present, all ions, positive or negative, migrate through the capillary in the same direction from the anode (injection end) to the cathode (outlet end). The analytes separate as they migrate due to differences in their mobility and are detected near the outlet end of the capillary. The output of the detector is sent to a data output and handling device such as an integrator or computer. The data is then displayed as an electropherogram, which reports detector response as a function of time. Separated entities can appear as peaks with different migration times, peak shapes, and peak areas in an electropherogram.

Analytes separated by capillary electrophoresis can be detected by UV or UV-Vis absorbance or fluorescence (natural fluorescence, chemical modification to introduce fluorescent tags or laser-induced fluorescence). Capillaries are typically coated externally with an opaque polymer for increased stability. Therefore, a small window must be etched in the coating, and the detector (UV or LIF) is then aligned at the window.

To obtain the identity of sample components, capillary electrophoresis may be directly coupled to a mass spectrometer. For this purpose, the capillary outlet is usually introduced into an ion source that utilises electrospray ionisation. The resulting ions are then analysed by the mass spectrometer.

The use of capillary electrophoresis for compound screening has been explored by others. For example, U.S. Pat. No. 6,299,747, U.S. Pat. No. 6,524,866, U.S. Pat. No. 6,432,651 and U.S. Pat. No. 6,837,977 (Cetek Corporation) describe use of a capillary electrophoresis method to identify and rank potential therapeutic ligands from a complex biological material sample. The method described in all four patents essentially requires a target of interest to be incubated with a complex biological material. A competitive ligand is then added to the mixture. After further incubation, the target/material/ligand mixture is injected into a capillary electrophoresis apparatus and the mobility of the target or the competitive ligand is tracked. The aim of all the methods described is to identify compounds that bind with a certain affinity (binding strength) to the target of interest. The patentee is particularly interested in medium to strongly binding compounds and the methods are designed to maximise the identification of such ligands over weakly binding compounds, particularly when such weakly binding compounds are present in the biological mixture in high concentration.

In general, weak binding compounds or ligands are identified as having a dissociation constant (K_{off}) of greater than 10 μM and an off rate (K_{off}) of more than 1.0 s⁻¹. Moderate to tight binding ligands have a K_{d} of 10 nM to 10 μM and a K_{off} of 0.01 to 1.0 s⁻¹. Strong binding ligands have a K_{d} of less than 10 nM and a K_{off} of less than 0.01 s⁻¹.

In particular, the Cetek methods rely on the dissociation of compounds present in the complex biological mixture and displacement by a competitive ligand. Even if weak-binding compounds are bound to the target on injection into the capillary, the fast off-rate due to the low affinity means the target/weak compound complexes are not detected at the end of the capillary run.

However, sometimes it is desirable to detect weak-binding compounds. In particular, weak compounds are desired in many of today's drug discovery screening programs as they offer an excellent chemical starting point for further optimisation into lead drug compounds and can extend a diminishing pool of potential drug-able compounds. For example, “fragment-based screening” is a common technique which starts with a primary screening assay to identify small molecular weight compounds with weak-binding to a therapeutic target. These weak compounds are subsequently optimised through a combination of biophysical and synthetic chemistry methods. Primary fragment-based assays must be able to screen at very high compound concentrations in order to detect weak affinities. However, most standard biochemical and cell-based assays cannot be used for this purpose due to matrix interference effects and other reasons. Thus, current fragment-based approaches utilise biophysical methods such as NMR, X-Ray crystallography, and isothermal calorimetry as screening assays as these procedures are able to tolerate high concentrations of test compounds.

However, all these methods have drawbacks and limitations, such as extensive assay development times, large reagent (e.g., target and test compound sample) quantity requirement, and low throughput.

Thus, there is a need for alternative methods to identify weak-binding compounds that do not suffer the drawbacks of the currently known methods and that fulfil the basic requirements of assays, namely high throughput, robust and simple.

The present invention provides a competitive binding assay based on a capillary electrophoresis method that substantially overcomes the disadvantages of current methods set out above and provides advantages for ligand screening, including the ability to detect weak ligands, tolerance to high concentrations of test compounds, rapid and simple assay development, physiological test conditions, low reagent consumption, and the potential for automation.

In particular, the invention resides in a capillary electrophoresis method, the method comprising the steps of:
i. Filling a capillary with a electrophoresis buffer and a biological target of interest;
ii. Optionally adding a test compound to the electrophoresis buffer;
iii. Preparing an injection sample comprising an injection buffer and a competing ligand and optionally a test compound;
iv. Introducing the injection sample into one end of the capillary;
v. Subjecting the injection sample to capillary electrophoresis;
vi. Determining the migration profile of the competing ligand; and
vii. Comparing the migration profile of the competing ligand in the absence and the presence of the test compound.

Thus, the present invention provides a simple and robust method for detecting compound binding and, in particular, binding of weak-binding compounds to a target of interest. While the Cetek methods rely on the dissociation of weak-binding compounds to ensure they are not detected, the present method overcomes the problem of weak-binding compound dissociation by adding the compound to the electrophoresis buffer and not allowing full equilibrium to be reached between the target, competing ligand, and test compound.

In addition, the method of the present invention overcomes the requirement for complex, lengthy assay development or the need for known test compounds of different affinities to optimise the assay. In many cases such known compounds are not available.

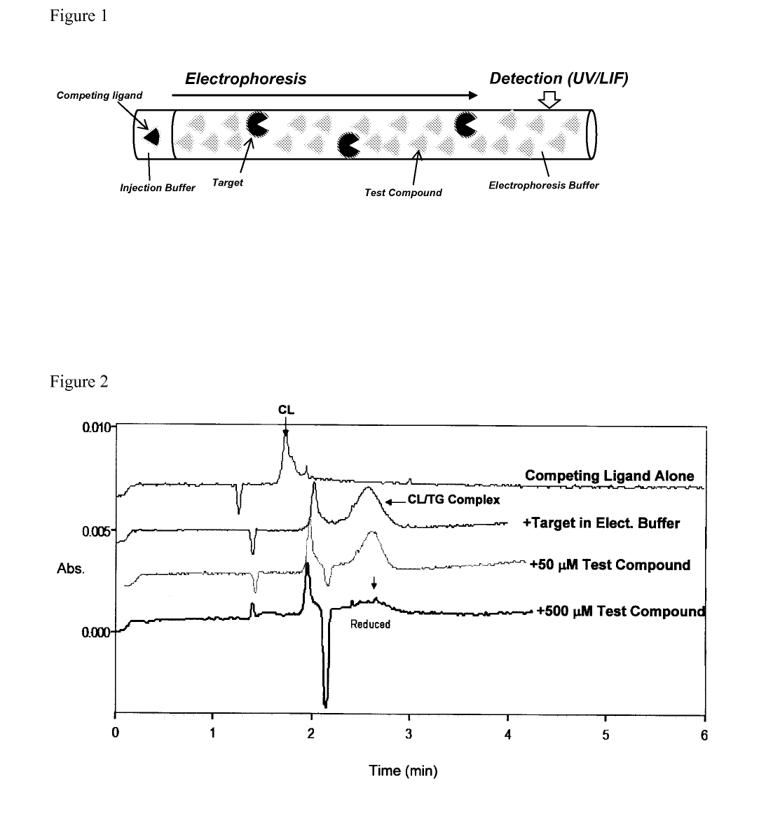

In more detail, the method monitors the electophoretic mobility of a “competing ligand” using the high resolution technique of capillary electrophoresis. The competing ligand is a known ligand that is selected based on having affinity for the therapeutic target of interest. As shown in FIG. 1, a sample of the competing ligand is injected (by hydrodynamic or electrokinetic injection) into a capillary filled with electrophoresis buffer containing the target, with or without test compound. The test compound may also be included in the injection sample to reduce a vacancy peak that can occur with strongly UV-absorbing compounds. A high electric field is applied and the competing ligand migrates through the capillary based on its charge-to-mass ratio. For uncharged competing ligands, electroosmosis may be used to facilitate competing ligand migration. The mobility of the competing ligand through the capillary may be monitored by either UV absorption or laser-induced fluorescence (LIF), with the detector located near the end of the capillary that lies furthest from the end into which the injection is made. Alternatively, mass spectrometry may be used as a detector at the end of the capillary. The detector data is displayed as an electropherogram.

The capillary electrophoresis apparatus comprises a thin, open-ended capillary tube into which the target and test compound are introduced into the electrophoresis buffer, and a competing ligand is subsequently injected. The capillary is ideally composed of fused silica glass with an inner diameter ranging from approximately 2 μm to 250 μm. The inner wall of the capillary may be uncoated or coated with a polymer, such as polyacrylamide, to decrease adsorption of analytes. Typical total capillary lengths range from about 7 cm to about 20 cm. Longer capillaries may be used to improve resolution. The method may also be carried out in capillaries in the form of open grooves or channels in a planar surface such as a fused silica or polymer microchip.

The capillary is ideally filled with an electrophoresis buffer that is compatible with the target, test compound and competing ligand. The particular buffer conditions appropriate for a specific target may be determined by experimentation according to methods well known to those of ordinary skill in the art. Ideally the electrophoresis buffer is a physiological buffer, such as but not limited to HEPES, MES, TAPS, CAPSO, TES, and Tris. These buffers are often used for biological analytes such as proteins as they provide physiologically relevant assay conditions for biological activity and enable a target to be screened in its functionally active state. Physiological buffers used for capillary electrophoresis also provide compatible electrophoretic conditions (low current, high field strength) for the method. Many other types of buffers and additives such as salts, detergents, dynamic coatings and co-factors may also be used and such buffers and additives will be known to those skilled in the art. A factor for consideration when choosing an electrophoresis buffer is that it should provide a relatively low current (e.g., <100 μA) to prevent Joule heating, which can be detrimental to the biological target. Alternatively, the capillary column may be cooled to reduce heating.

A target for use in the method of the invention is defined as any biological molecule, molecular complex or other biological entity, pure or impure, for which an affinity ligand is desired. Targets include but are not restricted to enzymes, receptors, reporters, G proteins, transporters, ion channels, functional proteins, regulatory proteins, nucleic acids, whole cells and membrane preparations.

Of particular interest are membrane-bound and membrane-associated proteins, including but not limited to G-protein coupled receptors (GPCRs). Such membrane-bound and membrane-associated proteins may be used in their native form, as cellular preparations, membrane preparations or in a form whereby the protein is no longer associated with the membrane, and has been stabilised by techniques including but not limited to mutagenesis, detergents, adjuvants, micelle formation and lipid vesicle formation.

There are very few biophysical techniques available to demonstrate direct interaction of small molecules with membrane proteins. Typically, fragment screening is performed using surface plasmon resonance (SPR) and target immobilised NMR screening (TINS). The disadvantage of both of these techniques is that they require immobilisation of the protein target. This often requires lengthy optimisation to ensure maintenance of target activity. However, the advantages of the capillary electrophoresis method of the present invention are that the protein does not require immobilisation or tethering, the reaction can take place in solution in physiological buffer and, as a consequence, the assay development time is rapid.

Another advantage of the method of the invention is that no or minimal target modification is required, thereby allowing use of a target in its substantially native configuration with no or minimal modification or conjugation. In contrast, other screening assays require chemical modification of a target or immobilisation of the target to a solid substrate. These steps can be expensive, time consuming, reduce or alter the activity of proteins and can produce aberrant results.

Because capillary electrophoresis is a microscale technique, only small amounts of target, test compound and competing ligand are required for screening (typically less than a microgram per assay). In contrast, alternative techniques such as NMR and isothermal calorimetry can consume large amounts of biological material. Thus, the target is ideally present at a concentration of between about 0.1 nM and 100 μM per capillary electrophoretic assay run.

Test compounds derived from chemical, biological, synthetic biological or any mixture of the aforesaid may be used. Ideally the test compounds are fragments, especially chemical fragments. It is advantageous if the compounds are in the molecular weight range of around 100 to 400 daltons, preferably around 100 to 300 daltons, because fragments can have higher ligand efficiencies than larger molecules. The ligand efficiency is the binding energy of a ligand normalised to its size, and compounds with high ligand efficiencies may be more suitable as starting points for chemical optimisation. While the method is able to detect test compounds and fragments having moderate or strong affinity to the target of interest, the investigation of compounds having weak affinities (e.g. K_{d}>10 μM) is particularly preferred. This is to enable a useful subset of potential therapeutics to be investigated since most currently known methods are optimised to detect only compounds with moderate and strong affinities. Table 1 provides approximate ligand affinities:

TABLE 1

| Ligand Affinity | Approximate Dissociation Constant (K_{d}) |
|---|---|
| Weak | >10 μM |
| Moderate | 10 nM-10 μM |
| Strong | <10 nM |

Capillary electrophoresis buffer is able to tolerate very high concentrations of test compounds (up to 2 mM) with no or minimal adverse effects on the output, unlike most biochemical and cell-based assays. This is believed to be because the separation component of capillary electrophoresis helps to prevent artifactual false positives/negatives. Therefore, the test compound is ideally present in the buffer at a concentration of up to about 2 mM.

Competing ligands used in the method of the present invention may be any suitable molecule, such as a chemical entity, peptide, protein, natural product, nucleic acid or synthetic biological molecule. The competing ligand must bind to the target and produce a detectable target peak complex, competing ligand peak shift, or reduced unbound competing ligand peak area when run by capillary electrophoresis. While the binding site of the competing ligand need not be known, knowledge of the binding site is preferable. The competing ligand may bind at the same site as the test compound or may bind to an allosteric site on the target.

Preferably the competing ligand is soluble in aqueous conditions and have an affinity to the target stronger than K_{d}=10 μM. The competing ligand or a competing ligand/target complex must also be detectable by methods compatible with capillary electrophoresis, such as UV/Vis absorbance, laser-induced fluorescence, or mass spectrometry. Advantageously, the competing ligand is injected into the capillary at a concentration of 0.1 nM or greater, preferably between about 10 μM and 2 mM.

A significant advantage of the method of the invention is the ability to detect weak-binding test compounds, even when using a competing ligand that has a stronger affinity than the test compound and is injected at a high concentration (high concentrations of competing ligand may be necessary for detection). In a normal equilibrium situation of all the components, the competing ligand will completely displace the weak test compound and the test compound would thus be undetectable. Indeed, this is seen with the methods described by Cetek. However, the high electric fields and fast run times used in the method of the present invention result in rapid migration of the competing ligand through the electrophoresis buffer and so the competing ligand does not have sufficient time to displace the test compound completely. Thus, test compounds that have a weak affinity for the target are detectable.

The principle of the method of the invention is as follows. Without test compound in the buffer, the target interacts with the migrating competing ligand and alters the ligand's charge-to-mass ratio, producing a change in the mobility of the competing ligand. The observed results depend on the affinity of the competing ligand to the target. For high affinity competing ligands, where the on-off kinetics of the interaction are slow relative to the run time, a competing ligand/target complex peak will be observed, in addition to any unbound competing ligand. For competing ligands with weaker affinity, where the on-off kinetics of the interaction are fast relative to the run time, the unbound competing ligand peak will shift in migration time as the ligand interacts in rapid equilibrium with the target (very little stable complex will be formed). A third possibility is that some of the competing ligand will bind to the target during electrophoresis resulting in a reduced unbound competitive ligand peak area, without producing an observable competing ligand/target complex peak. These are well-known principles of affinity capillary electrophoresis.

A test compound is then added to the buffer with the target. If binding occurs between the test compound and the target, a certain percentage of the target will be bound at any one time, depending on the test compound's affinity and concentration. As a result, less target will be available to bind to the injected competing ligand as it migrates through the capillary. The resulting competing ligand/target complex peak, shift of the competing ligand peak, or reduction in the competing ligand peak area, will be reduced or eliminated. Thus, two electropherograms (with and without test compound) are compared.

Detection of the competing ligand is ideally achieved through using UV/Vis absorption or laser induced fluorescence detection. In standard capillary electrophoresis instrumentation, a detector is placed near the end of the capillary to monitor the migration of the analyte(s). Typically, a small window is etched in the external polyimide coating which is typically present to protect the capillary from breakage. A UV/Vis or LIF detector is aligned at this window. The competing ligand or competing ligand/target complex requires a property that allows it to be detected. For example, the ligand may contain a chromophore that enables its detection by UV/Vis absorption. Alternatively, the ligand may include a fluorescent moiety (such as a covalently-attached fluorescent dye) that fluoresces when excited by a laser, if a LIF detector is used. The mobility of the competing ligand may then be monitored during electrophoresis.

The UV/Vis absorption or laser induced fluorescence outputs are typically displayed as electropherograms. Electropherograms are very similar to HPLC chromatograms in which time is plotted against units of detection (e.g., absorbance units or fluorescence intensity). Like chromatograms, analytes are represented by peaks with characteristic migration times, peak areas, peak heights, peak shapes etc. Unbound competing ligand peaks have a different peak profile compared to target-bound peaks or shifted peaks, allowing the operator to determine the extent of binding by comparing the resulting peaks to peaks obtained from electrophoretic runs including one or more test compounds.

It is also possible to use mass spectrometry (MS) as a detector. Commercial capillary electrophoresis-MS instruments and suitable interfaces are available. Unlike UV and LIF detection, MS detectors are placed at the end of the capillary and the analytes flow directly from the capillary into the MS, usually via an interface such as sheath-flow which provides a buffer compatible with MS.

To carry out the method of the invention, a competing ligand is selected which has a moderate to strong affinity to the target as defined by Table 1. The competing ligand should be detectable by UV/Vis absorption, LIF detection or mass spectrometry depending on the detection method used.

The optimal capillary electrophoresis conditions are determined (e.g., electrophoresis and injection buffer compositions and pH, temperature, voltage, injection time, competing ligand concentration, UV/LIF detection, coated vs. uncoated capillary, etc.) to give a detectable competing ligand peak. Optimising these conditions involves testing a panel of buffers, running conditions, and capillary types to produce a good (e.g., >3× signal-to-noise ratio, peak width <1 minute), reproducible (e.g., CV<10%) competing ligand peak. All these parameters are well known to those skilled in the art of capillary electrophoresis.

The optimal concentration (usually lowest concentration, to reduce target consumption) of target to add to the electrophoresis buffer that provides an easily detectable, competing ligand/target complex peak, shift in competing ligand migration, or reduction in the unbound competing ligand peak area, is then determined. For this purpose the target concentration is titrated in the electrophoresis buffer until a reproducible (e.g., CV<10%) profile is achieved.

The test compound(s) are added to the electrophoresis buffer at the desired screening concentration (e.g., 500 μM). The test compound will reach equilibrium with target present in the electrophoresis buffer. Multiple test compounds may be mixed for higher throughput provided the compounds are sufficiently soluble. The test compound may also need to be added to the injection sample to reduce a vacancy (negative) peak which can obscure the results. A vacancy peak can occur with UV detection if the test compound has a strong UV absorbance and is present only in the electrophoresis buffer and not in the injection sample.

Once target/test compound equilibrium has been reached, the competing ligand is injected into the capillary and the competing ligand/target complex peak or competing ligand migration is monitored. If a reduction in the competing ligand/target complex peak, shift in the migration time of the competing ligand, or an increase in the unbound competing ligand peak area is observed, this indicates that the test compound has bound to the target at the competing ligand (or allosteric) binding site.

A dose response curve may then be produced by testing different concentrations of test compound and plotting the test compound concentration against either the competing ligand/target complex peak areas, unbound competing ligand peak areas, or competing ligand mobility shift times.

The invention will now be described by way of non-limiting examples illustrated by the following figures in which:

FIG. 1 shows the capillary electrophoresis device with the electrophoresis buffer primed with target and test compound. The competing ligand is injected into the capillary on the left side of the figure and the electric field, once applied, drives the competing ligand through the electrophoresis buffer in which the test compound and target are contained. Detection occurs at a window near the end of the capillary at the right hand side of the figure.

FIG. 2 shows that the capillary electrophoresis-based method detects a weak-binding test compound when screened at a high concentration. In the lower plot, 500 μM of the weak-binding test compound significantly reduces the competing ligand/target (CL/TG) complex peak, indicating binding of the weak test compound to the target (human cyclophilin A). In the lower 3 plots, the unbound competing ligand peaks migrate slightly later due to reduced electroosmotic flow as a result of target interaction with the capillary walls. The large vacancy (negative) peak at 2.15 minutes in the lower two plots is due to the UV-absorbing test compound present in the electrophoresis buffer.

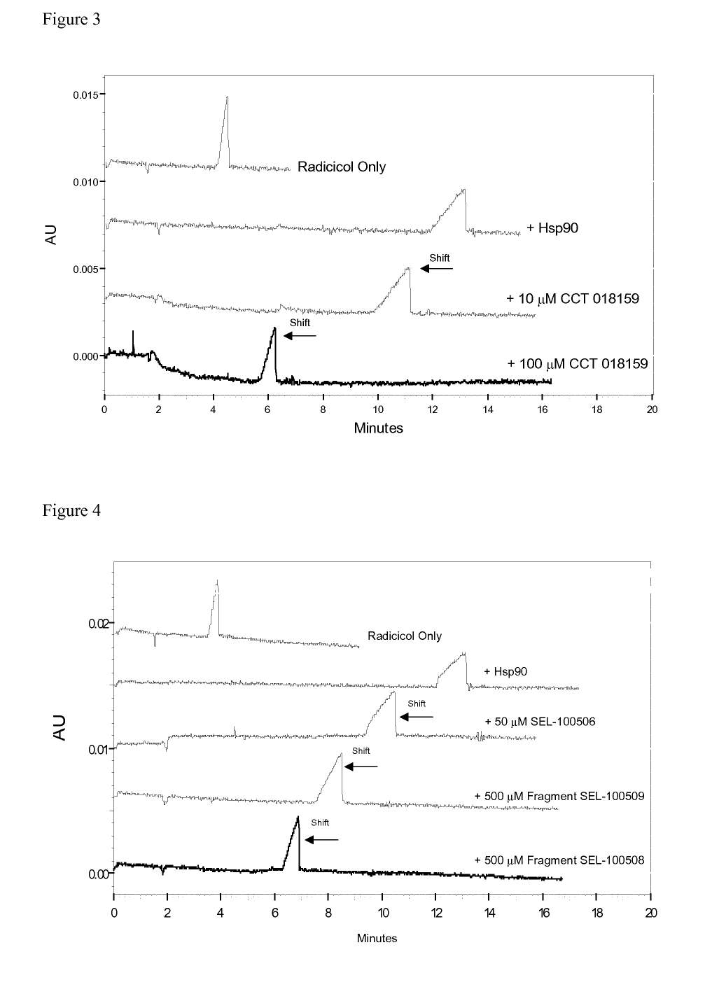

FIG. 3 shows the detection of a known ligand (CCT 018159) binding to human Hsp90. The top trace shows the competing ligand radicicol run alone. The second trace shows a shift in the radicicol peak to a much later migration time when the target Hsp90 is added to the electrophoresis buffer. The addition of increasing amounts of the test compound CCT-1018159 (third and fourth traces) results in a titratable inhibition of the radicicol shift as less Hsp90 becomes available to bind radicicol.

FIG. 4 shows the detection of three additional weak-binding Hsp90 ligands, including two chemical fragments. The top trace shows the competing ligand radicicol run alone. The second trace shows a shift in the radicicol peak to a much later migration time when Hsp90 is added to the electrophoresis buffer. The third trace shows the detection of a known ligand SEL-100506 when tested at 50 μM. The third and fourth traces show the detection of two chemical fragments SEL-100509 and SEL-100508 when tested at 500 μM.

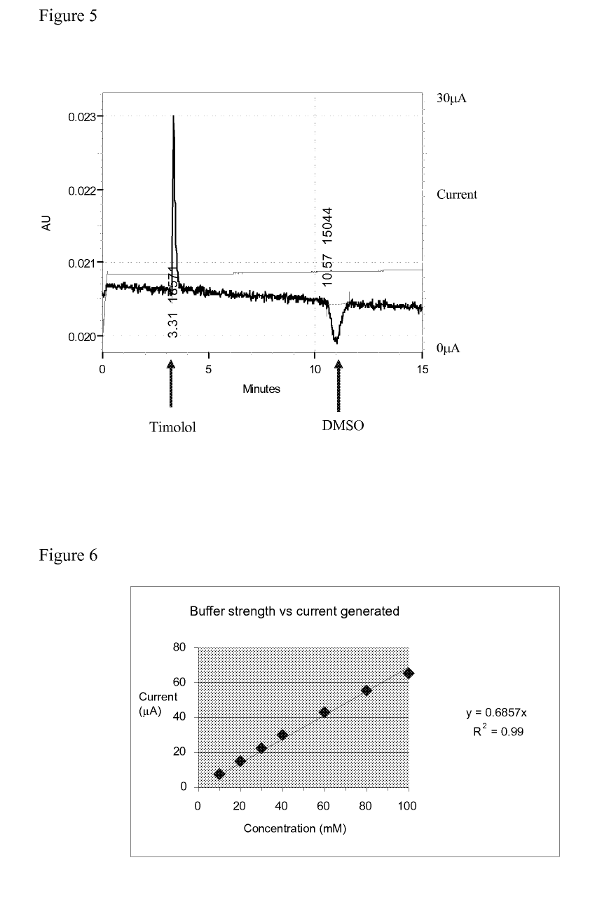

FIG. 5 shows an electropherogram of Timolol maleate (300 μM) at 280 nm in a coated capillary. Timolol migrates at 3.3 min followed by DMSO at 10.6 min. Conditions: Running buffer was Tris-HCl (10 mM, pH 7.5), Separation 15 kV. Current shown by the clean line (˜7.5 μA).

FIG. 6 shows the current (μA) generated in a coated capillary when a separation voltage of 15 kV was applied to a solution containing Tris buffer at different buffer strengths.

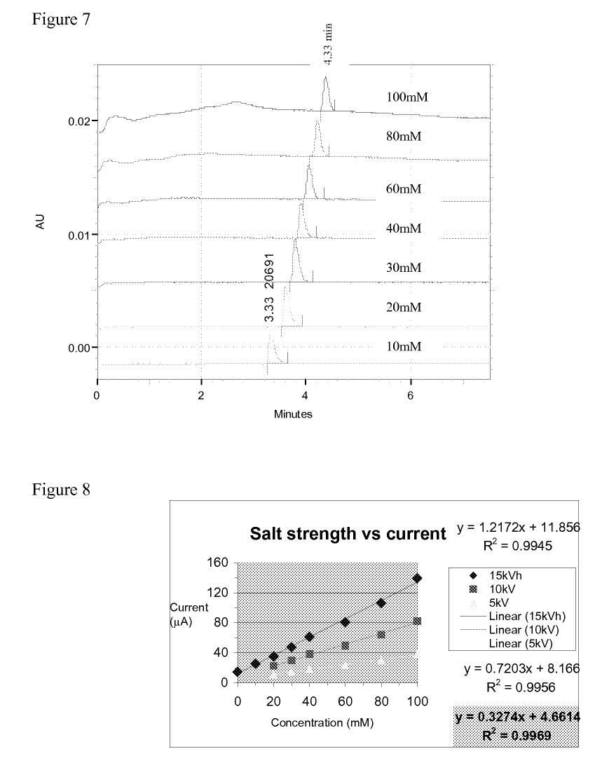

FIG. 7 shows the change in migration time of Timolol at 280 nm as Tris-HCl (pH7.5) buffer strength is altered. Bottom (10 mM) to top (100 mM) showing MT of 3.33 min to 4.33 min using separation voltage of 15 kV.

FIG. 8 shows the current (μA) generated in a coated capillary when a separation voltage of 5, 10 or 15 kV was applied to a solution containing Tris buffer (20 mM, pH 7.5) and various salt concentrations.

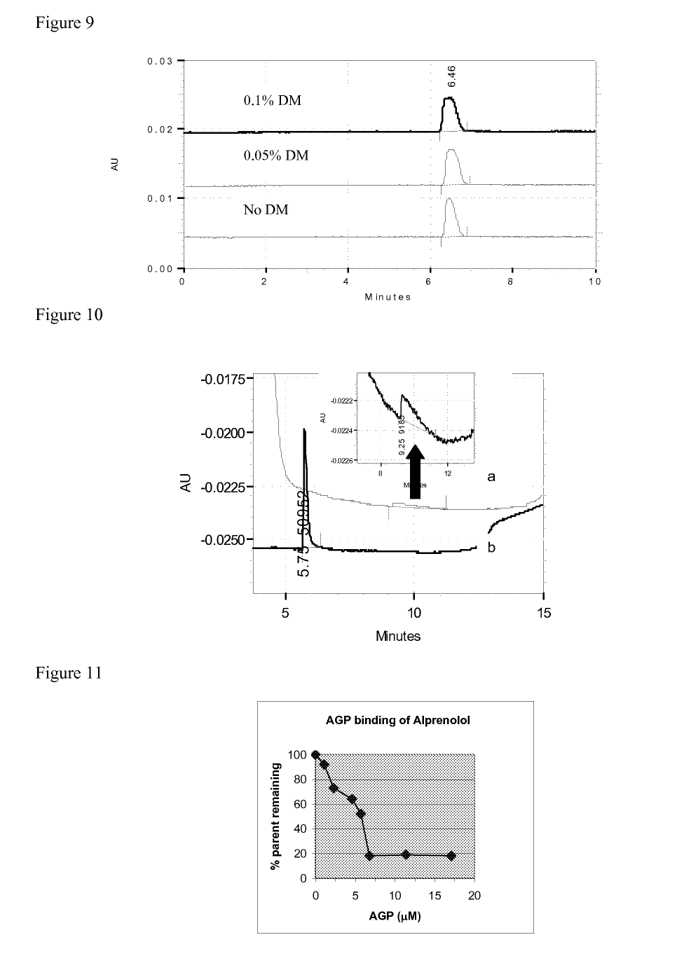

FIG. 9 shows that n-decyl-β-D-maltopyranoside (DM) has no effect on the migration time of Timolol at 280 nm. Tris buffer 20 mM containing 40 mM salt. Reverse polarity with injection from Outlet end, Separation voltage of 5 kV.

FIG. 10 shows an electropherogram of competing ligand Alprenolol (150 μM) at 200 nm with (a) and without (b) AGP in the running buffer. In the absence of AGP, Alprenolol elutes at 5.7 min. Inset graph is the zoomed in peak region as the AGP causes the baseline to drop between 3 and 5 min. The presence of AGP results in a decrease in the Alprenolol peak area and also a later shift in unbound Alprenolol migration time. Conditions: Running buffer was Tris-HCl (10 mM, pH 7.5, & NaCl (20 mM)) ±AGP (17.1 μM), Normal polarity, Separation 10 kV.

FIG. 11 shows the effect on the unbound peak area of Alprenolol (75 μM) injected into a coated capillary with ±AGP at various concentrations. Conditions: Running buffer was Tris-HCl (10 mM, pH 7.5, & NaCl (20 mM)) ±AGP, separation 10 kV.

### EXAMPLE 1

Human cyclophilin A (CypA) and a proprietary competing ligand (Ligand A) were used to demonstrate the aspect of the invention where a stable complex between the target and competing ligand is formed. The presence of a weak-binding test compound is detected by a reduction or disappearance of the target/competing ligand complex peak.

A stock solution of 50 mM Ligand A (MW˜400, K_{d}˜400 nM; competing ligand) was prepared in 100% DMSO, and diluted to 250 μM in electrophoresis buffer (10 mM HEPES pH 8.0, 0.1 mM DTT). This was the sample for injection.

A bare silica (Polymicro Technologies, AZ) capillary was used having a 20 cm total length, 50 μm inner diameter and external coating of a polyimide to prevent breakage. A small 0.5 cm window was carved in the coating at approximately 15 cm from one end of the capillary to align with the detector. The capillary was installed in a Beckman P/ACE MDQ Capillary Electrophoresis System as per the manufacturer's instructions. The inner wall of the capillary was uncoated, allowing electroosmotic flow to occur and enabling the net migration of all analytes towards the cathode. Prior to each run, the capillary was sequentially rinsed for 2 minutes each with 1N NaOH, water and electrophoresis buffer. Standard running conditions were 10 kV with capillary temperature set at 25° C. and UV detection at 254 nm.

In the first run (FIG. 2, top trace), Ligand A was hydrodynamically injected (0.5 psi 5 seconds) and electrophoresis applied with polarity towards the cathode. A Ligand A peak was observed at approximately 1.8 minutes. A vacancy (negative) peak was observed at approximately 1.2 minutes due to the DMSO present in the injected sample and represents uncharged species migrating with the electro-osmotic flow.

In the second run (FIG. 2, second trace), 1 μM of target CypA (Sigma-Aldrich) was added to the electrophoresis buffer and the run was repeated as before. A prominent new, broad peak was observed at approximately 2.3-2.8 minutes due to the formation of a complex between Ligand A and CypA during electrophoresis.

In the third run (FIG. 2, third trace), 50 μM of a proprietary weak test compound (K_{d}>30 μM) was added to both the injection sample and the electrophoresis buffer. As can be seen, there was no significant change in the profile, indicating that the weak test compound was undetectable at this concentration, which was expected due to its low affinity.

However, in the fourth run (FIG. 2, bottom trace), the weak test compound was added to the injection sample and electrophoresis buffer at a 10× higher concentration, 500 μM. A significant reduction in the Ligand A-CypA complex peak was seen. Thus, the concentration of the weak test compound was sufficiently high to bind a significant portion of CypA, preventing its ability to bind Ligand A. In summary, using this invention, the weak test compound was detectable at high concentrations.

There was no adverse effect on the system with test compound at a very high concentration (500 μM). This is unlike most biochemical assays, where compounds cannot be tested at such a high concentration as such concentrations tend to produce high false positive readings due to high background interference, signal quenching, and other artifactual problems. The unique separation capability of capillary electrophoresis helps to solve these issues.

### EXAMPLE 2

Human heat shock protein 90 (Hsp90) was used as the target and radicicol as the competing ligand to demonstrate the aspect of the invention where the competing ligand shifts in migration time upon interacting with the target during electrophoresis. The presence of a weak test compound is detected by a change in the migration time of the competing ligand.

A stock solution of 30 mM radicicol (Tocris Biosciences, MO; MW 364.8, K_{d}=20 nM) was prepared in 100% DMSO and diluted to 150 μM in electrophoresis buffer (10 mM Tris (7.5), 5 mM MgCl₂, 0.001% Tween-20). This was the injection sample.

The capillary was prepared and rinsed as in Example 1. In this example, the only difference in the capillary electrophoresis method was that the voltage applied was 15 kV.

FIG. 3 demonstrates the ability of this system to detect a known Hsp90 ligand. In the first run (FIG. 3, top trace), radicicol was hydrodynamically injected (0.5 psi 5 seconds) and electrophoresis applied with polarity towards the cathode as before. A radicicol peak was observed at approximately 4.1 minutes. A small vacancy (negative) peak is observed at approximately 1.4 minutes due to the DMSO present in the injected sample.

In the second run (FIG. 3, second trace), 50 nM of Hsp90 (Assay Designs, MI) was introduced into the electrophoresis buffer and the radicicol was injected and electrophoresed as before. A large migration shift of the radicicol to approximately 12-13 minutes was observed due to the interaction of the radicicol with the Hsp90 as it migrated through the capillary. Hsp90 has a low isoelectric point (pI˜5.5) and thus is highly negatively charged under these conditions (pH 8.0), which slows down the electrophoretic migration of the radicicol as the two components interact. Unlike in Example 1, a stable complex between the target and radicicol is not observed, indicating that more rapid equilibrium binding kinetics occur in this system.

In the third run (FIG. 3, third trace), 10 μM of a moderate affinity test compound, CCT 018159 (Tocris Biosciences, MO; reported IC₅₀=5.7 μM; Table 2) was added to both the injection sample and the electrophoresis buffer. As can be seen, there is an earlier shift in the migration time of radicicol to approximately 10-11 minutes, indicating that less Hsp90 was available to bind radicicol due to the presence of bound CCT 018159.

In the fourth run (FIG. 3, bottom trace), 100 μM of CCT 018159, a concentration well above its IC₅₀, resulted in an even faster migration of radicicol to approximately 6 minutes, indicating even less Hsp90 was now available to bind radicicol. Thus, the binding of a moderate affinity ligand is detectable at test concentrations near its IC₅₀ and the activity is titratable.

### EXAMPLE 3

The Hsp90/radicicol system was tested for the ability to detect three additional test compounds including a second known inhibitor and two weak-binding fragments (Table 2).

TABLE 2

| Compound | Structure | Class | MW |
|---|---|---|---|
| CCT 018159 | 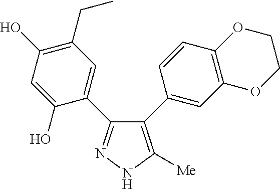 | Known Inhibitor | 352.39 |
| SEL-100506 | 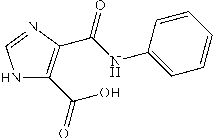 | Known Inhibitor | 231.21 |
| SEL-100508 | 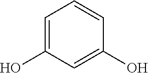 | Weak-binding Fragment | 110.11 |
| SEL-100509 | 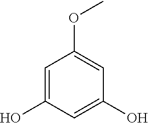 | Weak-binding Fragment | 140.14 |

SEL-100506, SEL-100508, and SEL-100509 (all solubilised in DMSO) were tested individually in the same basic setup as described for CCT 018159 in Example 2.

In FIG. 4, the top trace shows radicicol alone. The second trace shows the expected prominent later shift when Hsp90 is added to the electrophoresis buffer in the capillary as before. The third trace shows that 50 μM of the known ligand SEL-100506 was detectable as an earlier shift in produced in the radicicol peak. Likewise, the third and fourth traces show that two weak-binding fragments, SEL-100509 and SEL-100508, respectively, were also easily detectable at 500 μM test concentrations based on the faster migration of the competing ligand. Again, no adverse effect on the system was observed in the presence of such high concentrations of test ligands, demonstrating the superiority of this system over other biochemical methods for screening weak-binding ligands.

### EXAMPLE 4

Experiments were carried out to assess the flexibility of the capillary electrophoresis (CE) method of the present invention and to investigate the tolerance of the method to changes in salt, buffer, and detergent concentrations.

The capillaries used in this set of experiments had the following dimensions: 50 μm (inner diameter)×375 μm (outer diameter)×30 cm. The inner wall was coated with a permanently adsorbed layer of polyvinyl alcohol (PVA). This coating produces CE capillaries that have an uncharged surface, which minimises hydrophobic and electrostatic solute/wall interactions and reduces electroosmotic flow (EOF). These capillaries were preferred, over uncoated capillaries, as the protein can be easily washed out with water and the column reconditioned readily with water and buffer. All experiments were carried out using a Beckman MDQ capillary electrophoresis instrument with a single wavelength UV or Photo Diode Array Detector. Data were analysed using 32 Karat software Version 5.0 from Beckman Coulter. The system was conditioned before use every day and was set-up and used either in forward or reverse polarity with injection at either the Inlet or Outlet end.

The capillary temperature was set to 15° C. All buffers were prepared in Millipore grade water and filtered through 0.22 μm filters prior to use. Competing ligand and inhibitor stock solutions were made up in DMSO. The injection buffer (100 μl) used was Tris-HCl Buffer (Sigma T87602; pH 7.5), plus DMSO or inhibitor [1 μl, final concentration (f/c/) 1%]. The electrophoresis buffer (200 μl) contained Tris-HCl (pH 7.5) DMSO or inhibitor (1 μl, f/c/0.5%). Capillaries had a rinse cycle of 2 min water, 2 min buffer, followed by 1 min running buffer. Electrophoresis was carried out at a separation voltage of 15 kV Reverse Polarity, for 15 min (0.17 min ramp) while competing ligand was injected at 0.5 psi for 5 sec. After injection, the capillary was rinsed for 1 min with water.

4.1 Detection of Timolol Maleate by Capillary Electrophoresis

Initial experiments were performed to determine whether β1-adrenergic receptor ligands could be detected by UV with CE. A Tris buffer pH 7.5 was chosen as this is the buffer generally used for β1-adrenergic receptor assays (Serrano-Vega et al, Proc. Natl. Acad. Sci. 105 :877-882).

Timolol maleate ((S)-Timolol, Tocris 0649) was injected into the capillary containing electrophoresis buffer and the resulting electropherogram observed is shown in FIG. 5. Timolol had a migration time (MT) of 3.3 min and DMSO 10.6 min under the separation conditions of the run. The presence of the neutral DMSO shows there is some EOF present. This peak profile was highly reproducible in migration time and peak area (results not shown). Alprenolol (Tocris 2806; used later) gave a similar reproducible profile although with a different migration time (not shown).

The results demonstrate that Timolol maleate is a suitable ligand for testing the tolerance of CE to different buffer, salt and detergent concentrations.

4.2 Effect of Buffer Strength

Joule heating (resistive heating) is inevitable when a current passes through an electrolyte (Enenhuis C J & Haddad P R, (2009) Electrophoresis. 30(5):897-909; Cetin B & Li D (2008) Electrophoresis. 29(5):994-1005). In capillary electrophoresis excessive Joule heating needs to be avoided otherwise detrimental effects may occur in the capillary, such as bubble formation, denaturation of proteins, peak broadening and changes in migration time of the competing ligand. A current upper limit of 30 μA was set to avoid any Joule heating effects. As any ions present in the running buffer can cause an increase in the current, it is advisable to determine the buffer strength and salt limitations in CE.

4.2.1 Effect of Buffer Strength on Current

Tris-HCl buffer (pH7.5) between 10 and 100 mM was tested. The appropriate buffer was placed into vials in the CE instrument and electrolysed at 15 kV until a steady current was obtained (no ligand present). The current was noted.

TABLE 3

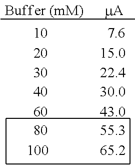

As shown in Table 3 and FIG. 6, a linear relationship was observed between the buffer strength and the current generated (R²=0.99). From the measurements, all those in the grey shaded area of Table 3 give too high a current, giving rise to Joule heating effects. This shows that with 15 kV, up to 40 mM Tris buffer (pH 7.5) can be safely used before the current limit of 30 μA is reached.

4.2.2 Effect of Buffer Strength on Timolol Migration Time

Timolol maleate was injected into a capillary containing the different strength electrophoresis buffer and the resulting electropherograms observed are shown in FIG. 7. Timolol migration time (MT) changed from 3.33 min with 10 mM buffer to 4.33 min with 100 mM buffer. The baseline deteriorated when using 60 mM or greater buffer. Timolol peak area was constant over the buffer range tested.

In summary, the migration time of the competing ligand Timolol was affected by the buffer strength. Up to 40 mM Tris-HCl (pH 7.5) can be tolerated at a separation voltage of 15 kV before the current threshold of 30 μA is reached.

4.3 Effect of Salt Concentration on Current

The salt tolerance of the CE system was investigated. A buffer of 20 mM Tris-HCl (pH7.5) was chosen with a current of 15 μA in the absence of salt and a separation voltage of 15 kV (see Table 3), i.e. half the maximum allowed before Joule effects occur. Solutions of this buffer were prepared with varying salt concentrations (0-100 mM NaCl (Fischer BP358-1)). The solution was electrolysed until a steady current was obtained at various separation voltages. The current was noted.

As expected, the current increased with increasing salt concentrations. Linear relationships were observed between the concentration of salt added and the current generated for all separation voltages applied with R² values >0.99 (see Table 4 and FIG. 8). The grey shaded area of Table 4 shows where the current threshold of 30 μA is exceeded.

TABLE 4

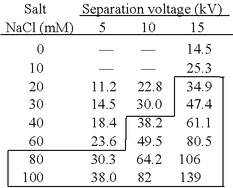

The separation voltage can be decreased to allow higher salt concentrations to be used if necessary. Initially Tris buffer (20 mM, pH 7.5) with 40mM NaCl was used for some experiments but this was found limiting as the maximum separation voltage that could be used was limited to 7.5 kV. Thus, the salt concentrations were measured again using 10 mM buffer strength. These results are shown in Table 5 which sets out the current (μA) generated when various separation voltages and salt concentrations were used with 10 mM Tris-HCl buffer (pH 7.5).

TABLE 5

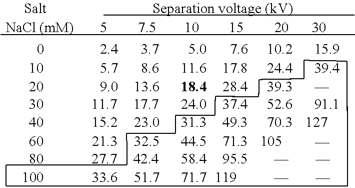

As expected, the current increased with increasing salt concentrations and reducing the voltage enabled greater salt concentrations to be tolerated before exceeding the 30 μA current threshold. The grey shaded area of Table 5 shows where the current threshold of 30 μA is exceeded. The conditions in bold (10 mM Tris and 20 mM NaCl) were those used in the binding experiments outlined in section 4.5 below.

In summary, the addition of salt affects the current but a variety of buffer and salt concentrations can be used depending upon the separation voltage required. Thus, the CE system of the present invention is able to tolerate a wide range of buffer and salt concentrations.

### 4.4 Effect of Detergents

The effects of detergents such as n-decyl-β-D-maltopyranoside (DM; Anatrace D322) and n-dodecyl-β-D-maltopyranoside (DDM; Anatrace D310) on the current and competing ligand migration time were investigated as a prelude to use of the CE method for the screening of membrane-bound proteins, such as GPCRs. Concentrations of detergent were used above and below the critical micellar concentrations (CMC) for each of the detergents. The CMC in water of DDM (0.0087%) is 10-fold lower than that for DM (0.087%).

Detergents DM and DDM were initially made up in water at 20% w/v, sub-aliquoted and stored in a freezer at −80° C. An aliquot was removed, thawed and diluted with buffer to the appropriate working solution concentration before use. The remaining aliquot of detergent was refrozen. Working solutions were generally used for up to 48 h before discarding.

4.4.1 Effect of DM on Current

Tris Buffer (20 mM, pH 7.5) containing 40 mM NaCl (see Table 4) with differing detergent concentrations of DM (0-0.5%), were electrolysed until a steady current was obtained at various separation voltages. The current was noted.

TABLE 6

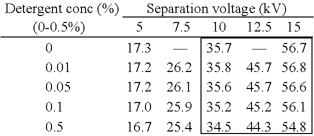

Table 6 shows the current (μA) generated when various separation voltages were applied to a solution containing Tris buffer (20 mM, pH 7.5) and 40 mM NaCl and various DM concentrations. The grey shaded area shows where the current threshold of 30 μA is exceeded. Addition of DM had little effect on the current even at ˜5 times its CMC.

### 4.4.2 Effect of DDM on Current

Tris Buffer (20 mM, pH 7.5) with 40 mM NaCl and differing detergent concentrations of DDM (0-0.05%), were electrolysed until a steady current was obtained at various separation voltages. The current was noted.

TABLE 7

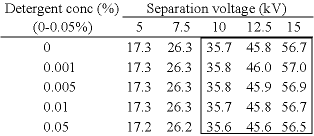

Table 7 shows the current (μA) generated when various separation voltages were applied to a solution containing Tris buffer (20 mM, pH 7.5) and 40 mM NaCl and various DDM concentrations. The grey shaded area shows where the current threshold of 30 μA is exceeded. DDM had little effect on the current even at ˜5 times its CMC.

4.4.3 Effect of Detergents on Competing Ligand Migration Time

Using a 20 mM Tris-HCl (pH7.5) buffer containing 40 mM NaCl, the effect of DM at 0.05 and 0.1% (just above and below the CMC) was observed on the Timolol migration time.

As shown in FIG. 9, the detergent had little effect on the migration time or peak area of Timolol with the migration time being constant at around 6.4 min for all samples. Similarly, DM had little effect on the competing ligand, Alprenolol migration time or peak area at 0.01% (data not shown).

In summary, DM and DDM had insignificant effect on the current at concentrations up to five times their respective CMC. At around the CMC of the different detergents, no effect on the competing ligand migration time was observed. This suggests that CE can tolerate buffer conditions necessary for the analysis of membrane-bound proteins and other targets requiring the presence of detergents.

4.5 Competing Ligand Binding in CE

To demonstrate the principle of the CE technique, experiments were carried out to determine if a mobility shift of the Alprenolol could be detected in the presence of alpha-1-acid glycoprotein (AGP). AGP is known to bind a number of drugs including Alprenolol and Timolol (Fournier T et at (2000) Biochim Biophys Acta. 1482(1-2):157-71; Belpaire F M et at (1982) Eur J Clin Pharmacol. 22(3):253-256).

A 99% pure sample of AGP was obtained from Sigma (G9885) and a stock of 2.23 mM made up in water. This was diluted 10-fold with buffer/NaCl and the resultant solution used in experiments. FIG. 10 shows competing ligand Alprenolol (150 μM) injected into the capillary with or without AGP present in the running buffer.

The Alprenolol peak shows a clear shift in migration time from 5.75 to 9.3 min in the presence of AGP (FIG. 10). The area of the Alprenolol peak also decreased from 50952 to 9185 AU. This is approximately 18% of the parent peak area, indicating some of the Alprenolol bound to AGP present in the electrophoresis buffer.

Table 8 and FIG. 11 show the migration time and the percentage of the parent peak remaining after injecting samples of Alprenolol (75 μM) into the electrophoresis buffer containing various concentrations of AGP. As the concentration of AGP increased, the peak of Alprenolol shifted from 5.7 min without AGP to 9.3 min with 17.1 μM AGP. Alprenolol binding to AGP was shown to be dose dependent with 6.8 μM of AGP binding sufficient Alprenolol to reduce the peak to around 18% of the parent, with an observed shift of around 0.8 min.

In addition, the peak area decreased with increasing AGP concentration, showing that a percentage of Alprenolol was binding to AGP during electrophoresis. The free Alprenolol peak area was not completely abolished with 17.1 μM AGP but remained around 18%. The percentage of Alprenolol remaining free was very similar to the reference value obtained for plasma protein binding: 79% bound—i.e. 21% free (Burchholz L et at (2002). Euro J Pharmacol Sci. 15(2):209-215).

TABLE 8

| AGP | AGP | MT | 1 |
|---|---|---|---|
| (μl) | (μM) | (min) | (% of parent) |
| 0 | 0 | 5.7 | 100% |
| 1 | 1.1 | 5.7 | 92% |
| 2 | 2.3 | 5.9 | 73% |
| 4 | 4.6 | 5.9 | 64% |
| 5 | 5.7 | 6.0 | 51% |
| 6 | 6.8 | 6.5 | 18% |
| 10 | 11.4 | 7.1 | 19% |
| 15 | 17.1 | 9.3 | 18% |

The results indicate that CE can detect an interaction between the β-adrenergic receptor competing ligand and AGP. This suggests that a suitable competing ligand/target system can be developed under buffer and salt conditions similar to those envisioned for the analysis membrane-bound proteins, such as GPCRs. Detergents were not tested in this system as they would likely have denatured the non-GPCR target AGP.

In a screening program, test compounds will be added to the CE buffer system and “hits” will be detected by an abolishment or reduction in the competing ligand shift, and an expected increase in the competing ligand peak area, due to competition with the Alprenolol for the target binding site.

4.6 Conclusions

The experiments carried out in this example have shown that capillary electrophoresis is amenable to detecting ligands in a wide variety of salt, buffer and detergent conditions useful for a broad range of therapeutic targets. To keep the current below 30 μA to prevent Joule heating, adjusting the voltage enables a variety of buffer/salt combinations to be used as shown in Tables 2 and 3. Addition of detergent DM or DDM to the system, at just above or below their respective CMC, did not significantly affect the current generated or the probe ligand migration time.

AGP was investigated as a model protein which was also known to bind the β-adrenoreceptor probe ligands. In the presence of AGP, the shift of the competing ligand migration time was found to be concentration dependent suggesting that CE was able to detect the interaction between the competing ligand and protein.

It will be appreciated that fluorescent competing ligands could also be used. The advantage of using a fluorescent competing ligand is that 1000-fold less competing ligand is required as well as possibly a reduction in the amount of target protein required. Table 12 sets out the minimum requirements that are anticipated to be required for the different phases of screening using the capillary electrophoresis method of the present invention.

TABLE 9

| | Probe ligand - | | | | Probe ligand - | | | |
|---|---|---|---|---|---|---|---|---|
| | UV detection | | | | LIF detection | | | |
| | | | Probe | | | | Probe | |
| | Target | | ligand | | Target | | ligand | |
| Compatibility testing | 100 | ug | 200 | ug | 100 | ug | 200 | ng |
| Assay development | 200 | ug | 300 | ug | 200 | ug | 300 | ng |
| Screening/per 1500 | 1.5 | mg | 2 | mg | 1.5 | mg | 2 | ug |
| library + confirmations | | | | | | | | |
| IC₅₀ determination/ | 20 | ug | 30 | ug | 20 | ug | 30 | ng |
| compound | | | | | | | | |

1. A capillary electrophoresis method, the method comprising the steps of:
i) Filling a capillary with an electrophoresis buffer, a test compound and a biological target of interest;
ii) Preparing an injection sample comprising an injection buffer and a competing ligand;
iii) Introducing the injection sample into one end of the capillary;
iv) Subjecting the competing ligand to capillary electrophoresis;
v) Determining the migration profile of the competing ligand; and
vi) Comparing the migration profile of the competing ligand in the absence and the presence of the test compound.

2. A method according to claim 1, wherein the capillary has an internal diameter of between 2 μm and 250 μm

3. A method according to claim 1, wherein the electrophoresis buffer is a physiological buffer.

4. A method according to claim 1, wherein the target is present in the electrophoresis buffer in its substantially native conformation.

5. A method according to claim 1, wherein the target is substantially unmodified and/or unconjugated.

6. A method according to claim 1, wherein the target is present in the electrophoresis buffer at a concentration of between 0.1 nM and 100 μM per capillary electrophoretic assay run.

7. A method according to claim 1, wherein the test compound has a molecular weight of 100 to 2,000 daltons.

8. A method according to claim 7, wherein the test compound has a molecular weight of 100 to 300 daltons.

9. A method according to claims 1, wherein the biological target is a membrane-bound or membrane-associated protein.

10. A method according to claim 9, wherein the membrane-bound or membrane-associated protein is present in the electrophoresis buffer in its substantially native conformation as a cellular preparation, membrane preparation or in a form whereby the protein is no longer associated with the membrane and has been stabilised by techniques including mutagenesis, detergents, adjuvants, micelle formation and lipid vesicle formation.

11. A method according to claim 10, wherein the biological target is a G-protein coupled receptor.

12. A method according to claim 1, wherein the test compound is present in the electrophoresis buffer at a concentration of up to 2 mM.

13. A method according to claims 1, wherein the method further includes adding the test compound to the injection buffer with the competing ligand when test compound is present in the electrophoresis buffer.

14. A method according to claim 1, wherein the competing ligand has a dissociation constant for the target that is less than 10 μM.

15. A method according to claim 1, wherein the competing ligand is injected at a concentration of 0.1 nM or greater.

16. A method according to claim 15, wherein the competing ligand is injected at a concentration of between 10 μM and 2 mM.

17. A capillary electrophoresis method for detecting test compounds having a weak-binding for the target, wherein the dissociation constant of the test compound is greater than 20 μM, the method comprising the steps of:
i) Filling a capillary with an electrophoresis buffer, a test compound and a biological target of interest
ii) Preparing an injection sample comprising an injection buffer and a competing
iii) Introducing the injection sample into one end of the capillary;
iv) Subjecting the competing ligand to capillary electrophoresis;
v) Determining the migration profile of the competing ligand; and
vi) Comparing the migration profile of the competing ligand in the absence and the presence of the test compound.
